(19) United States
(12) Patent Application Publication
(10) Pub. No.: US 2018/0058295 A1
(43) Pub. Date: Mar. 1, 2018

(54) Thermoelectric heat energy recovery module

(71) Applicants: Mark A. Junio, San Antonio, TX (US); Terry R. McCauley, San Antonio, TX (US); Joseph S. McDowell, San Antonio, TX (US); Victoria A. Wattson, San Antonio, TX (US)

(72) Inventors: Mark A. Junio, San Antonio, TX (US); Terry R. McCauley, San Antonio, TX (US); Joseph S. McDowell, San Antonio, TX (US); Victoria A. Wattson, San Antonio, TX (US)

(73) Assignee: Quantum Industrial Development Corp. & Texas A&M University - San Antonio, San Antonio, TX (US)

(21) Appl. No.: 15/330,341

(22) Filed: Sep. 1, 2016

(51) Int. Cl. F01N 5/02; B60K 6/26; H01L 35/30; H01L 35/32

(52) U.S. Cl. CPC F01N 5/025; B60K 6/26; H01L 35/30; Y10S 903/906; B60Y 2200/92; B60Y 2400/206; H01L 35/325

(57) ABSTRACT

This embodiment is a Stirling-Electric Hybrid automotive exhaust module generator device for converting waste heat energy into electrical energy by employing the Seebeck Effect. The disclosure herein describes how the invention converts heat energy, from hot exhaust gases, from the operation of an automotive external combustion engine (e. g. Stirling Cycle engine), into electrical energy which is fed back into the electrical system of the Stirling-Electric Hybrid Automobile (U.S. Pat. No. 7,726,130 B2) minimizing losses due to the second law of thermodynamics. The improvements on the art in this disclosure focuses on employing a plurality of thermopiles and materials with improved coefficients of thermal conductivity and increasing residence time of the hot exhaust gases by inducing turbulent flow through the module generator device in conjunction with external cooling plate(s), heat sink(s); in the form of a plurality of pin(s), on the interior and exterior surface(s) of the module generator device.

### REFERENCES CITED

Automotive Waste Heat Conversion to Electric power using Skutterudite, TAGS, PbTe and BiTe, LaGrandure et al. Visteon Corporation, 2006
Thermal Conductivity of Selected Materials, Powell et al. National Bureau of Standards, 1966
Thermoelectric Handbook, Micro to Nano, D. M. Rowe, 2006
Disposition of Radioisotope Thermoelectric Generators Currently Located at the Oak Ridge National Laboratory, J. Glenn et al. WM2012 Conference, Feb. 26-Mar. 1, 2012

### U.S. PATENTS DOCUMENTS CITED

U.S. Pat. No. 7,726,130 B2, Stirling-Electric Hybrid Automobile, McDowell, June, 2010 Research Collaboration Between
Texas A&M University-San Antonio and Quantum Industrial Development Corp.

### BACKGROUND OF THE INVENTION

### The Field of the Invention

The application of a thermopile module generator device to generate electrical energy from waste heat energy carried by exhaust gases from an external combustion Stirling-Electric Hybrid Automobile (ibid) is novel. Additionally, previous designs of automotive thermoelectric generators, did not take advantage of both active and passive systems of heat energy transfer. Previous designs did not employ a plurality of heat sink(s) pin(s) which have superior heat transfer characteristics to those of heat transfer fins, due to a more favorable surface area to mass ratio typically found in the heat sink(s) pin(s) design. Additionally, heat sink(s) pin(s) do not inhibit heat transfer by boundary layer effects as is typical with the laminar fluid flow with the employment of heat transfer fins. Previous automotive applications could not take advantage of more efficient heat sink materials such as Aluminum, which would melt at the higher temperatures of operation typically found in the exhaust manifold of an internal combustion engine. Additionally, the geometric configuration of the heat sink(s) pin(s), improves heat energy transfer rates from the exhaust gases to the thermopile(s) array(s) by creating turbulent fluid flow within the exhaust module conduit which increases residence time of the exhaust gas molecules, allowing for a more complete heat energy transfer to the thermopile(s) array(s), while minimizing back pressure within the exhaust system.

Exhaust gas temperatures from an external combustion automotive Stirling Cycle engine typically range from 150° C. to 250° C. when measured at the exhaust manifold. The current state of the art of thermopile power generation requires at least a 50° C. temperature difference (ΔT) to generate power at optimum efficiencies. The current invention utilizes lower exhaust gas temperature ranges found in the external combustion automotive Stirling Cycle engine which allows for the employment of materials with more efficient and higher coefficients of thermal conductivity than can be currently employed with higher temperatures found in the exhaust gases produced by an internal combustion engine. The external combustion exhaust gas temperatures are significantly lower than those of conventional internal combustion engines, this lower temperature range presents an opportunity for an improvement on the art since high temperature range thermopiles are not as efficient as lower temperature range thermopiles due, in part, because at lower temperatures, it is less difficult to maintain more favorable temperature differences, from the hot side of the thermopile to the cold side of the thermopile. This improvement is due, in part, to the increase in thermal conductivity at lower temperatures of heat sink materials. Heat sink materials are more efficient at lower temperature ranges due to the inverse relationship between the coefficient of thermal conductivity and temperature. The coefficients of thermal conductivity for materials at high temperatures are lower than the thermal conductivity of the same material at a lower temperature which means as temperatures drop the coefficient of thermal conductivity increases. The lower temperatures of the Stirling Cycle engine exhaust gases provide for an improved rate of heat energy transfer to heat sink materials resulting in a more favorable ΔT from the hot side of the thermopile to the cold side when the more efficient heat sinks materials are employed.

The technical problems that the present invention resolves are not limited to those mentioned above, and those that are not mentioned shall be clearly understood by a person skilled in the art by examining the specifications of the present invention disclosed herein.

### Description of Related Art

Thermopile technology is based upon the thermoelectric effect, or Seebeck effect. By applying a temperature difference to a pair of dissimilar metallic junctions in an electrical circuit, an electrical voltage is generated.

The practice of using thermopiles to generate electrical power, by means of applying heat energy from a variety of heat sources, including radioisotopes, has been employed by both the U.S. Department of Energy and the National Aeronautics and Space Administration (NASA). These applications include Radioisotope Thermoelectric Generators (i.e. RTGs) for remote power supplies for equipment deployed in Antarctica, and spacecraft power supplies (i.e. Pioneer 10 Spacecraft). Thermopiles are more efficient as ΔT increases.

Previous automotive applications of thermopiles have had limited success in part because the temperatures of exhaust gases from internal combustion engines can reach 800° C. when measured at the exhaust manifold. Conventional heat sink materials, stable at these high temperatures, are not as thermally conductive as they are at lower temperatures resulting in less favorable ΔT across the thermopile for the generation of electrical voltage. These higher exhaust gas temperatures limit the types of materials that can be employed to maintain favorable rates of efficient heat energy transfer. Additionally, previous designs have not employed both active, and passive, heat energy transfer techniques, and more effective heat energy transfer methodologies as disclosed herein the present invention, such as heat sink(s) pin(s), rather than less efficient heat transfer fins. None of the previous designs were specific to a series hybrid electric automotive application employing an external combustion Stirling Cycle engine. The operation of an automotive Stirling Cycle engine produces exhaust gases at significantly lower temperatures than exhaust gas temperatures produced by current internal combustion engines. These lower temperatures provide for more efficient application of thermopile technology since a broader range of more effective heat sink materials are stable at these lower temperature ranges. It is a general characteristic that heat sink materials have a greater coefficient of thermal conductivity at lower temperatures. There is roughly a 50% loss in thermal conductivity of a heat sink composed of Iron at 800° C. when compared to the thermal conductivity of the same material at 200° C. An example of a heat sink material available for use with the external combustion Stirling Cycle engine is Aluminum. Aluminum, when employed as a heat sink material, has superior coefficient of thermal conductivity to that of Iron. Aluminum cannot be used at the higher exhaust gas temperatures produced by internal combustion engines, since exhaust gas temperatures are well above the melting point of 660° C. These physical properties of Aluminum make it unsuitable as a heat sink material at the higher temperatures found in the exhaust gases of the internal combustion engine, but make it one of many ideal materials to be employed when recovering heat energy from the exhaust gases produced by an external combustion Stirling Cycle engine.

Information disclosed in this Background of the Invention section, is only for enhanced and detailed understanding of the general background of the invention, and should not be taken as an acknowledgement, nor any form of suggestion, that this information forms the prior art already known to a person skilled in the art.

### BRIEF SUMMARY

The various aspects of the present invention are directed to provide a thermoelectric module generator device to convert waste heat energy from exhaust gases, produced by an automotive external combustion Stirling Cycle engine, into electrical energy by employing the Seebeck effect.

In the aspect of the present invention, a thermoelectric generator module device of a Stirling-Electric Hybrid Automobile (ibid), may include an inlet conduit to transfer the flow of exhaust gases from the exhaust system, be it an exhaust manifold or exhaust pipe, into the module generator device where interior heat sink(s) pin(s)s, which may be of varying lengths, may be arranged in a plurality of alternating offset, overlapping rows, to facilitate turbulent flow of the exhaust gases, such that there is no direct line of sight path as the exhaust gases flow from the inlet to the outlet. The overall geometric shape of the device may be such that the surface area of the top surface and the bottom surface of the device exceeds the surface area of the lateral surface(s) of the device by a factor of two or higher. The rows of heat sink(s) pin(s) may be affixed to the top and bottom interior surface(s) of the device to absorb heat energy from the exhaust gases and thermally conduct the heat energy to the top and bottom interior surface(s) of the module conduit. The volumetric dimensions of the module conduit may be fabricated to accommodate twice the volumetric capacity of the exhaust pipe or manifold, to minimize exhaust system backpressure. A plurality of the interior heat sink(s) pin(s) may be arranged geometrically, to provide for a fluid dynamic porosity and permeability of 50% or higher.

On the lateral side(s) of the module conduit, in close proximity to the outlet on the outer surface(s) edge, an aerodynamically contoured air foil may be affixed at an angle to direct air flow toward the area where the outlet is vented to the atmosphere. The air foil may take advantage of air movement under the frame of the automobile as the automobile moves along the roadway directing air past the air toil, to create a Venturi effect to assist in evacuating the exhaust gases out of the module conduit to further minimize exhaust system back pressure.

The outer surface(s) of the top and bottom of the module conduit may have a plurality of layers of thermopile(s) in an array(s) affixed to the surface(s) via a thermally conductive adhesive and/or fixture(s). The plurality of the thermopile(s) array(s) may be wired in series and/or parallel in wiring harnesses, which may be shielded in a wiring conduit, to satisfy the specifications of the electrical system of the Stirling-Electric Hybrid Automobile (ibid). The heat energy absorbed by the heat sink(s) pin(s) on the interior surface(s) of the module conduit may be conducted through the inner surface(s) of the module conduit to the outer surface(s) of the module conduit to the hot side of the thermopile(s) in the thermopile(s) array(s) by thermal conduction.

A cooling plate(s), which may be composed of a material with a high coefficient of thermal conductivity, which may include, but not limited to, a material composition of ceramic, ceramic composite(s), metallic alloy and/or metallic alloy composite(s), incorporating into the matrix of the material Cubic-Boron Nitride and/or other substance(s) to provide for improved thermal conductivity. The cooling plate(s) may be affixed to the cold side of the plurality of the thermopiles in the thermopile(s) array(s) via a thermally conductive adhesive and/or fixture. A cooling fluid may circulate through a plurality of tubular channel(s) in a pattern to include, but not limited to, a serpentine pattern, to circulate the cooling fluid to and from a radiator device(s) to expel excess waste heat energy.

The radiator device(s) may be composed of material with a high coefficient of thermal conductivity to include but not limited to, ceramic, ceramic composite(s), metallic alloy and/or metallic alloy composite(s), incorporating into the matrix of the material Cubic-Boron Nitride and/or other substance(s) to provide for improved thermal conductivity. The radiator device(s) may be affixed with a fan(s), which is driven either by electricity or mechanically, to provide motive power to the fan, for the purpose of directing ambient air over, and/or through, the radiator device(s) to expel excess waste heat energy thermally conducted to the surface(s) of the radiator device(s) from the cooling fluid. This radiator device(s) may be part of the overall cooling radiator(s) system of the Stirling-Electric Hybrid Automobile (ibid) or separate from the overall radiator(s) cooling system.

The outer surface(s) of the cooling plate(s) may be affixed with a plurality of heat sink(s) pin(s) by a thermally conductive adhesive and/or fixture(s) such that passive transfer of heat energy from the surface(s) of the cooling plate(s) to the heat sink(s) pin(s) is accomplished. The heat sink(s) pin(s) may expel excess waste heat energy passively via air movement under the frame of the automobile as the automobile moves along the roadway, directing air over and/or through the arrangement of heat sink(s) pin(s).

### BRIEF DESCRIPTION OF THE DRAWINGS

FIG. 1 is a diagrammatic view of the outlet end of the Thermoelectric Heat Energy Recovery Module (THERMO) Generator device for hybrid-electric automotive application such that the module generator device converts waste heat energy into electrical energy by employing the Seebeck Effect in accordance with the embodiment of the present invention. The Thermoelectric Heat Energy Recovery Module Generator device may be fabricated as a tubular conduit, and/or other geometric shape(s), which allows for the flow of exhaust gases through the interior of the module conduit from the inlet to the outlet to be then vented to the atmosphere. Opposite of the outlet, the inlet end of the module generator device may be connected to the exhaust manifold or the exhaust pipe or other conduit to transfer the exhaust gases before venting to the atmosphere. The outlet of the module generator device may be vented to the atmosphere or connected to other Thermoelectric Heat Energy Recovery Module Generator device(s) in series, before venting to the atmosphere. The interior surface(s) of the module conduit may have a plurality of heat sink(s) pin(s) (5), affixed, to include but not limited to, the upper and lower interior surface(s) in a plurality of offset overlapping rows such that there is no direct line of sight flow path as the exhaust gases move from the inlet to the outlet of the module conduit of the module generator device. The geometric arrangement of the plurality of the interior heat sink(s) pin(s) (5) may be designed in such a manner as to facilitate turbulent fluid flow of the exhaust gas molecules. The interior heat sink(s) pin(s) (5) may be of varying lengths.

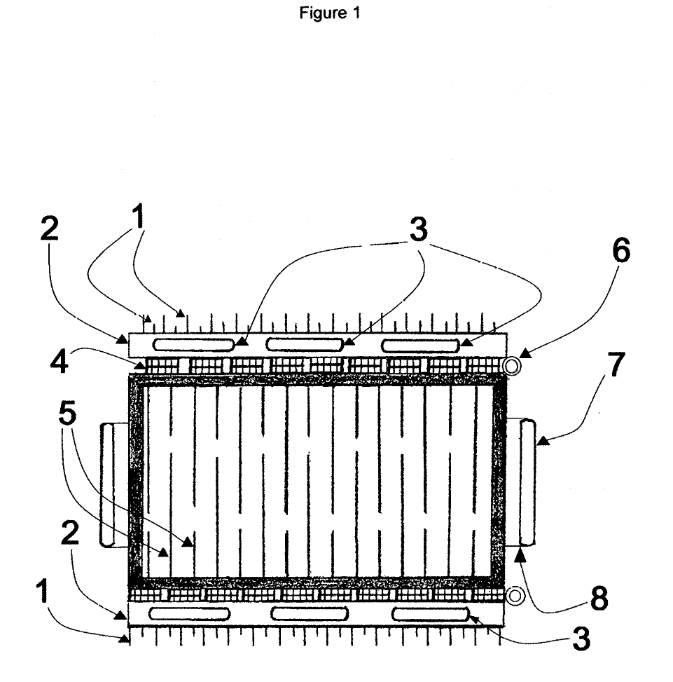

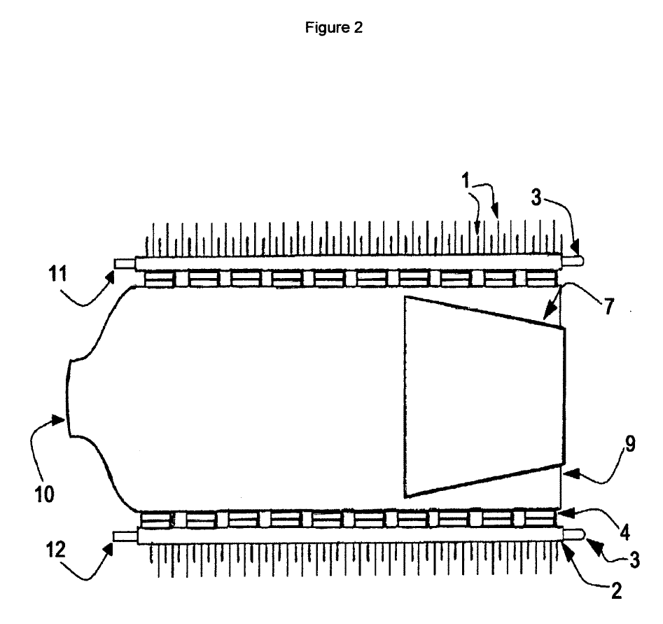

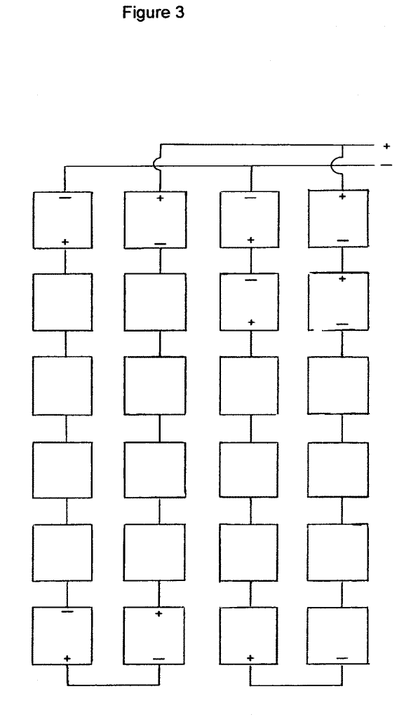

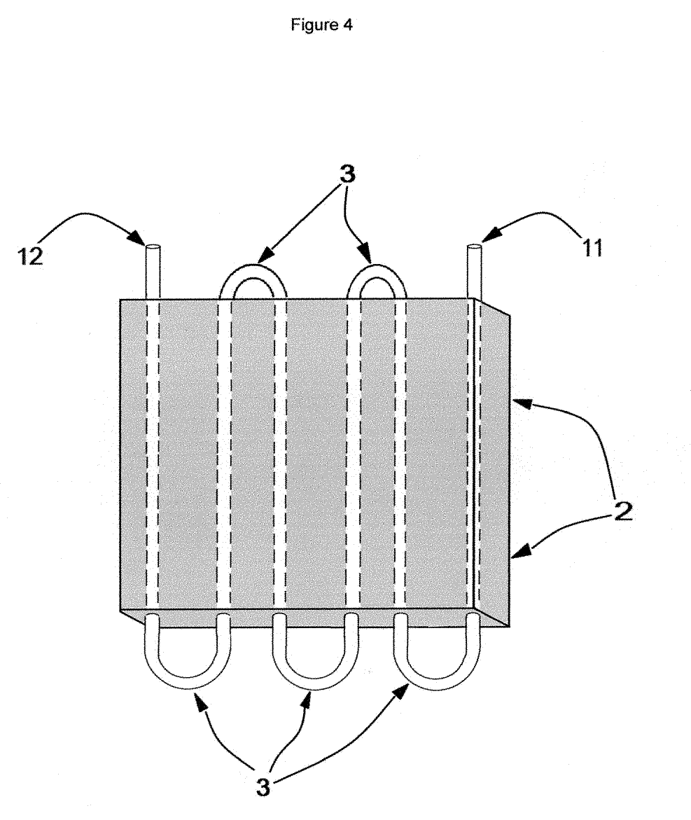

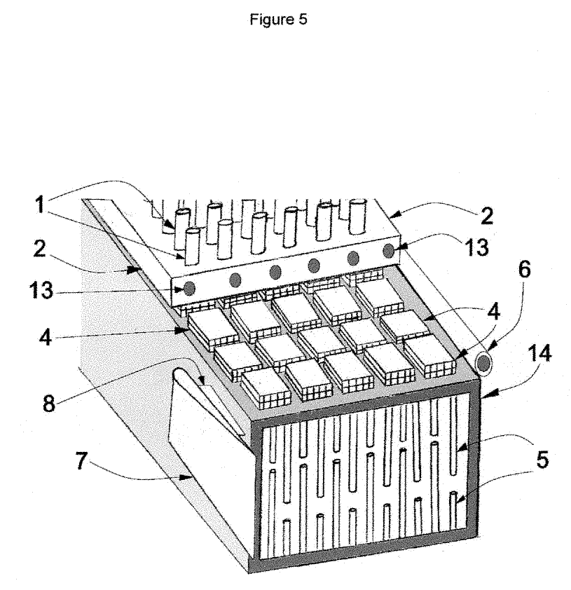

A plurality of thermopile(s) array(s) (4) may be affixed, via thermally conductive adhesive and/or fixture(s), to the outer surface(s) of the module generator device to absorb heat energy from the outer surface(s) of the module generator device. The geometric arrangement of the plurality of the thermopile(s) are arrayed such that they may be in a plurality of layers, wired in series and/or parallel and connected to the electrical system of the Stirling-Electric Hybrid Automobile (ibid) via a conduit (6) or other shielding device.

A cooling plate(s) (2) may be affixed via thermally conductive adhesive and/or fixture(s) to the outer most surface(s) of the thermopile(s) array(s) (4) in such a manner as to absorb heat energy from the surface(s) of the thermopile(s) (4) arrayed on the surface(s) of the module conduit. The cooling plate(s) (2) may have a plurality of tubular channels through which cooling fluid may flow from one tubular channel to the adjacent tubular channel via external return loops (3) in a pattern similar to, but not limited to, a serpentine pattern such that the cooling fluid circulates through the majority of the mass, and/or area, of the cooling plate(s) (2).

A plurality of exterior heat sink(s) pin(s) (1) of varying length may be affixed to the outer surface(s) of the cooling plate(s) (2) and geometrically arranged in offset overlapping rows, to take advantage of air movement under the frame of the Stirling-Electric hybrid Automobile (ibid) as the automobile moves along the roadway; the air movement will help to expel heat energy derived from the module generator device to the ambient air.

Affixed to the lateral side of the module conduit by means of a bracket (8) or other fixture, is an air foil (7) to direct air flow past the outlet of the module generator device.

FIG. 2 is a diagrammatic representation lateral view of the exterior surface(s) of the module generator device. The outermost part of the module generator device depicts the geometric arrangement of the alternating overlapping rows of varying length heat sink(s) pin(s) (1) arrayed such that there is sufficient surface area to expel heat energy to the ambient air by facilitating turbulent flow through and across the exterior heat sink(s) pin(s). The exterior heat sink(s) pin(s) are affixed to the outer surface of the cooling plate(s) (2). The cooling plate(s) has external recirculation return loops (3) for the cooling fluid. At the inlet (10) end of the module generator device the cooling plate(s) (2) has a cooling fluid inlet (11) and a cooling fluid outlet (12) for the circulation cooling fluid. Between the cooling plate(s) and the exterior surface of the module conduit are the thermopile(s) array(s) (4). At the outlet end of the module generator device (9) is the air foil (7) affixed to the lateral surface(s) to direct air flow over past the outlet end (9) of the module generator device. The volumetric expansion from the inlet (10) of the module conduit to the outlet (9) of the module conduit, is expanded from the volumetric capacity of the exhaust pipe and/or manifold, by a factor of two or more.

FIG. 3 is a diagrammatic representation of the plurality of thermopile(s) array(s) affixed to the outer surface(s) of the module generator device wired in series, and/or parallel to meet the electrical specifications of the electrical system of the Stirling-Electric Hybrid Automobile (ibid).

The wiring may be bundled into a conduit to carry the electrical power to the electrical system of the Stirling-Electric Hybrid Automobile (ibid). The plurality of thermopile(s) array(s) may be arranged in a plurality of layers.

FIG. 4 is a diagrammatic representation of the cooling plate(s) (2) with tubular channel(s) for the circulation of cooling fluid, which may circulate the cooling fluid from a radiator device to the cooling fluid inlet (11), then after circulating through the cooling plate(s) (2) the cooling fluid flows from to the cooling fluid outlet (12) back to the radiator device to expel excess waste heat energy to the ambient air. The cooling fluid return loops (3) are external to the cooling plate(s) (2) and transfer the cooling fluid from one tubular channel to the adjacent tubular channel in the cooling plate(s) (2).

FIG. 5 is a layered cut away diagrammatic representation of the surface(s) of the module conduit in direct contact with the thermopile(s) (4) arrayed in a plurality of layers with a cut away diagrammatic representation of the cooling plate (2) in direct contact with the thermopile(s) array(s) (4). Heat sink(s) pin(s) are diagrammatically represented having direct contact with the outer surface(s) of the cooling plate(s) (1). Cooling fluid may circulate through the cooling plate(s) (2) by means of tubular channels (13). The interior of the module generator device has heat sink(s) pin(s) (5) which may be of varying lengths and may be arranged in a plurality of alternating offset, overlapping rows, such that there is no direct line of sight path which facilitates turbulent flow of the exhaust gases as the gases flow from the module generator device inlet to the module generator device outlet. On the lateral side of the module conduit is an air foil (7) affixed to the outer surface of the module by means of a bracket (8) or other fixture. The thermopile(s) array(s) are wired in series and/or parallel and the wiring is bundled into a conduit (6) or other shielding device to connect to the electrical system.

### DETAILED DESCRIPTION OF THE PREFERRED EMBODIMENTS OF THE INVENTION

### Thermoelectric Heat Energy Recovery Module (THERMO) Generator for Application in a Stirling-Electric Hybrid Automobile

This embodiment of the invention is a Stirling-Electric Hybrid automotive exhaust module generator device for converting waste heat energy into electrical energy by employing the Thermoelectric Effect, also known as the Seebeck Effect. The disclosure herein describes how the invention converts heat energy, from hot exhaust gases, from the operation of an automotive external combustion engine (e. g. Stirling Cycle engine), into electrical energy which is fed back into the electrical system of the Stirling-Electric Hybrid Automobile (U.S. Pat. No. 7,726,130 B2) minimizing losses due to the second law of thermodynamics. The improvements on the art in this disclosure focus on taking advantage of the first law of thermodynamics by increasing residence time of the hot exhaust gases through the module conduit by employing heat sink(s), in the form of a plurality of pins, on the interior surface(s) of the module conduit. Additional improvements on the art may be implemented by fabricating the module conduit with materials having higher coefficients of thermal conductivity such as ceramic, ceramic composite(s), metallic alloys and/or metallic alloy composite(s) which may include Cubic Boron Nitride and/or other materials high coefficients of thermal conductivity, within the material matrix of the module conduit.

The fabrication of the module generator device may consist of components to include the module conduit, interior heat sink(s) pin(s), thermopile(s) array(s), electrical wiring conduit, cooling plate(s), external heat sink(s) pin(s) and an air foil. These components are configured to draw a maximum amount of heat energy out of the module generator device and convert it into electrical energy by maintain a favorable ΔT.

As exhaust gases move from the module conduit inlet of the module generator device, to the outlet, the plurality of interior pin(s) of the heat sink(s) create turbulent flow such that micro-vortices move the exhaust gas molecules over more heat transfer surface(s) area(s) of the module conduit with a resultant of significant improvement in heat energy transfer rates than can be currently attained with heat transfer fins due to the boundary layer effect typical in laminar fluid flow. Additionally, this configuration of the plurality of the interior heat sink(s) pin(s) will resolve the problem of creating back-pressure in the exhaust system that is inherent in heat transfer fin designs due to laminar fluid flow boundary layer effects. The plurality of the interior heat sink(s) pin(s) transfers the heat energy to the outer surface(s) of the module conduit where, on the outer surface of the module conduit, a plurality of thermopile(s) absorb the heat energy conducted through to the outer surface of the module conduit. The plurality of thermopile(s), on the outer surface of the module conduit, are wired in both series and/or parallel bundles, to meet the voltage specifications of the electrical system. The wiring bundles may be connected to the electrical system via wiring conduit or other shielding device. The plurality of the thermopile(s) on the outer surface of the module conduit composes an array(s), which may be affixed to the hot outer surface(s) on the module conduit via thermally conductive adhesive and/or fixture such that the thermopile(s) are in direct contact with the outer surface(s) of the module conduit, to provide for heat energy transfer via thermal conduction. The thermopile(s) array(s), on the outer surface(s) of the module conduit, may be in a plurality of layers, each layer in direct contact with the adjacent layer to transfer heat energy, one from the other, by thermal conduction. Cooling plate(s) may be affixed in direct contact to the outer most surface(s) of the thermopile(s) array(s) with a thermally conductive adhesive and or fixture(s) to provide for heat energy transfer via thermal conduction. The cooling plate(s) may be composed of a material with a high coefficient of thermal conductivity to include, but not limited to ceramic, ceramic composite(s), metallic alloy and/or metallic alloy composite(s) which may include Cubic-Boron Nitride of other substance(s) to improve thermal conductivity. The cooling plate(s) is to provide for a significant ΔT between the two major surface(s) of the thermopile(s) array(s), which are in direct contact with both the outer surface(s) of the module conduit and the inner surface(s) of the cooling plate(s) such that an electrical voltage is generated when a minimum threshold of ΔT is achieved. The cooling plate(s) may transfer heat energy from the thermopile(s) array(s) to the ambient air, both actively and passively. The active cooling may be provided by the employment of a serpentine arrangement of tubular channels in the cooling plate(s) through which cooling fluid circulates to and from the cooling plate(s) via a radiator(s) to expel heat energy from the circulating fluid to the ambient air. The cooling fluid circulation may flow though the plurality of tubular channels in the cooling plate(s) from the cooling fluid inlet(s) into the plurality of tubular channels successively via a plurality of external tubular return loops such that cooling fluid is transferred from one tubular channel successively to the adjacent channel(s) and then to the cooling fluid outlet(s). The outlet(s) of the cooling plate(s) may circulate cooling fluid to the radiator(s), which may be separate from the main radiator system, via a circulating pump which may be driven electrically of mechanically. The passive cooling may be accomplished by affixing a plurality of external heat sink(s) pin(s) to the outer surface(s) of the cooling plate(s) to take advantage of the air movement under the automobile frame, to expel heat energy to the ambient air, as the automobile moves along the roadway.

What is claimed:

1. A Thermoelectric Heat Energy Recovery Module (THERMO) Generator device comprising of a tubular conduit, or other geometrically shaped conduit form, having an inlet and an outlet, arrayed with a plurality of heat sink(s) pin(s) of varying lengths which are in direct contact with the interior surface(s) of the module conduit with an inlet to be attached to the exhaust system of a Stirling-Electric Hybrid Automobile (ibid) and an outlet to vent the exhaust gases to the atmosphere.

2. The geometric arrangement of the plurality of the heat sink(s) pin(s), of varying length, on the interior surface(s) of the module conduit is such that the rows of the heat sink(s) pin(s) are in an array such that each consecutive row of heat sink(s) pin(s) are offset one from the other.

3. The geometric arrangement of the plurality of heat sink(s) pin(s) of varying length on the opposite surface(s) of the interior surface(s) of the module conduit, one from the other, are arrayed in such a manner as to be overlapping, without direct contact with the heat sink(s) pin(s) which are in direct contact with the opposite interior surface(s) of the module conduit in a similar geometric array as detailed in claim 2.

4. The module conduit will have an inlet and an outlet, one opposite from the other.

5. The inlet, according to claim 4, will be connected to the exhaust system of the automobile in accordance with claim 1.

6. The volumetric dimensions of the module conduit are fabricated to accommodate a minimum of twice the volumetric capacity of the exhaust system in accordance with claim 1.

7. The geometric arrangement of the plurality of the heat sink(s) pin(s) in claim 3, is such that there is a porosity and permeability of 50% or higher, throughout the interior space of the module conduit, from the inlet to the outlet, in accordance with claim 1.

8. In accordance with claim 1, the heat sink(s) pin(s) may be affixed to the interior surface(s) of the module conduit with a thermally conductive adhesive and/or fixture(s).

9. The outer surface(s) of the module conduit may have a plurality of thermopile(s) in direct contact with the outer surface(s) and/or in direct contact one with another in a single or a plurality of layers, with one layer in direct contact with the outer surface(s) of the module conduit and subsequent outermost layer(s) in direct contact with the cooling plate(s).

10. In accordance with claim 9, the plurality of thermopile(s) on the outer surface(s) of the module conduit may be affixed to the outer most surface(s) of the module conduit with a thermally conductive adhesive and/or fixture(s) and/or similarly affixed one to the other in a plurality of layers with the innermost layer in direct contact with the outer most surface(s) of the module conduit.

11. The plurality of thermopile(s) in claim 9 may be wired in series and/or parallel and may be connected to the electrical system of the Stirling-Electric Hybrid Automobile by means of a conduit(s) or other shielding device(s).

12. The plurality of thermopiles in claim 9 may be sealed against the weather and/or moisture.

13. The outer most surface(s) of the layer(s) of the plurality of thermopile(s) in claim 9 will be in direct contact with a cooling plate(s).

14. In accordance with claim 13 the cooling plate(s) will be affixed in direct contact to the outer most layer(s) of the plurality of thermopile(s) in claim 9 with a thermally conductive adhesive and or fixture(s).

15. The cooling plate(s) in claim 13 may have a plurality of tubular channel(s) through it.

16. The cooling plate(s) in claim 13, having a plurality of tubular channel(s) through it, in accordance with claim 15, such that the tubular channel(s) are geometrically arranged to provide for a maximum extent of area and/or of mass of the cooling plate(s).

17. The plurality of tubular channels in the cooling plate(s) in claim 15 may be connected one to the other via external return loops such that the return loop(s) transfers the cooling fluid to the adjacent tubular channel(s) successively, one from the other.

18. The cooling plate(s) in claim 13 may have a cooling fluid circulating to, and from, the cooling plate(s) through a cooling fluid inlet and a cooling fluid outlet.

19. The cooling plate(s) in claim 13 may have the circulating cooling fluid connected to a radiator(s) by means of a conduit and/or piping.

20. The circulating cooling fluid in claim 18 may circulate from the cooling plate(s) in claim 12 to, and from, the radiator(s) in claim 19 by means of a circulating pump.

21. The radiator(s) in claim 19, may have a fan to force air over and/or through the radiator(s) surface(s).

22. The fan in claim 21, may be driven either mechanically or electrically.

23. The circulating pump in claim 20, may be driven either mechanically or electrically.

24. The outermost surface(s) of the cooling plate(s) in claim 13, may be in direct contact with a plurality of heat sink(s) pin(s) of varying lengths.

25. The plurality of the heat sink(s) pin(s) in claim 23, may be affixed to the outermost surface(s) of the cooling plate(s) in claim 13, with a thermally conductive adhesive and/or fixture(s).

26. The plurality of heat sink(s) pin(s) in claim 23, may be geometrically arranged on the outermost surface(s) of the cooling plate(s) such that the rows of the heat sink(s) pin(s) are in an array such that each consecutive row of heat sink(s) pin(s) are offset one from the other.

27. Affixed on the lateral side of the outlet end of the module conduit in claim 4, there is an air foil(s).

28. The air foil(s) in claim 27, may be fixed at an angle to direct air flow toward the outlet end detailed in claim 4 such that when the automobile moves along the roadway, air flow may be directed past the outlet end of the module generator device.
